(19) United States
(12) Patent Application Publication
(10) Pub. No.: US 2006/0254521 A1
(43) Pub. Date: Nov. 16, 2006

(54) Electron cyclotron resonance (ecr) plasma source having a linear plasma discharge opening

(76) Inventors: Joachim Mai, Nobitz (DE); Dietmar Roth, Oberlungwitz (DE)

Correspondence Address: JORDAN AND HAMBURG LLP, 122 EAST 42ND STREET, SUITE 4000, NEW YORK, NY, 10168, US

(21) Appl. No.: 10/571,161

(22) PCT Filed: Sep. 8, 2004
(86) PCT No.: PCT/DE04/02027

§ 371 Date: Mar. 29, 2006

(30) Foreign Application Priority Data
Sep. 8, 2003 (DE) 103 41 239.5

(51) Int. Cl. C23C 16/00

(52) U.S. Cl. 118/723 MA

(57) ABSTRACT

The invention relates to an electron cyclotron resonance (ECR) plasma source having a linear plasma discharge opening (9, 27, 28, 30), comprised of a plasma chamber, inside of which a centered wave distributor is provided, and having a multi-pole magnetic field arrangement in the area of the linear plasma discharge opening. The centered wave distributor consists of at least two separate wave distributors (3, 4) that are placed inside a respective partial plasma chamber (1, 2, 21, 22, 32, 23). A linear partial plasma discharge opening (7, 8, 23, 24, 34, 35) and multi-pole magnetic field arrangements (10, 11, 38, 39) are provided on each partial plasma chamber (1, 2, 21, 22, 32, 23). The at least two linear plasma discharge openings (7, 8, 23, 24, 34, 35) are arranged with regard to one another in such a manner that, together, they form at least one plasma discharge opening (9, 27, 28, 30) of the ECR plasma source.

### BACKGROUND OF THE INVENTION

The invention relates to an ECR (electron cyclotron resonance) plasma source having a linear plasma discharge aperture on a plasma chamber that simultaneously acts as external conductor and in which a centric wave distributor is present that is connected to a device for generating a high frequency and to a multi-pole magnetic field arrangement in the area of the linear plasma discharge aperture. All technically acceptable and permitted frequency ranges can be considered for the high frequency. In practice frequencies between 13.56 MHz and 2.45 GHz have especially proved themselves.

Numerous plasma generating devices are known from the prior art. DE 198 12 558 A1 describes an apparatus for generating linearly expanded ECR plasmas (Electron Cyclotron Resonance plasmas). An internal conductor is connected to a device for generating microwaves (910 MHz to 2.45 GHz) and is arranged coaxially in a well-conducting external coaxial waveguide that simultaneously limits the plasma space. The tube-shaped plasma space has, parallel to the longitudinal axis, a gap-shaped aperture, and one multi-pole magnetic arrangement for generating a static magnetic field is provided on each side of the longitudinal axis. If microwaves are fed via the internal conductor (wave distributor) into the plasma space that has been flooded with a carrier gas, a plasma forms in the plasma space. In the area of the gap-shaped aperture the plasma is substantially strengthened with strong electrical field components using the magnetic field of the multi-pole magnetic arrangement.

A linearly expanded plasma can be very advantageously produced with such a device. However, it is disadvantageous that the plasma density in the longitudinal axis of the gap-shaped aperture fluctuates relatively widely and, transverse to the longitudinal axis, has a parabola-shaped expansion with a relatively small apex radius of curvature.

### SUMMARY OF THE INVENTION

The object of the invention is thus to suggest a linear ECR plasma source of the type cited in the foregoing with which a large-area homogeneous plasma can be created at the plasma discharge aperture.

The core of the invention is comprised in that at least two linear ECR plasma sources having a wave distributor and multi-pole magnetic field arrangement, known per se, are inventively further developed into an efficient linear ECR plasma source having at least one plasma discharge aperture.

For many applications, an ECR plasma source having two partial plasma chambers will be adequate. However, an ECR plasma source in accordance with the invention can also have three or more partial plasma chambers, especially when matched to the specific shape of the substrates or arrangement of the substrates on substrate carriers. Similarly, the ECR plasma source can have one or two plasma discharge apertures and, when there are three or more partial plasma chambers, can also have more plasma discharge apertures.

The ECR plasma source can have specific plasma discharge apertures that are substantially dependant on the position of the actual plasma-generating partial plasma chambers and their position relative to one another.

The ECR plasma source can be advantageously further developed such that in addition to the multi-pole magnetic arrangements in the area of the partial plasma discharge apertures one or a plurality of additional multi-pole magnetic arrangements are securely or movably arranged outside of the partial plasma chambers. Thus the plasma formation in the interior of the partial plasma chambers can be influenced in a specific manner.

Additional advantageous designs are described in greater detail in the following exemplary embodiments.

### BRIEF DESCRIPTION OF THE DRAWINGS

FIG. 1 is a section through a schematic of a first embodiment of the invention;

FIG. 2 is a section through a schematic of a second embodiment of the invention;

FIG. 3 is a section through a schematic of a third embodiment of the invention;

FIG. 4 is a section through a structural design of a fourth embodiment of the invention; and

FIG. 4b is a perspective view of the fourth embodiment.

### DETAILED DESCRIPTION OF THE INVENTION

The advantage of the inventive ECR plasma source is particularly comprised in that by overlaying at least two individual plasmas, a dense and largely homogeneous plasma can be generated with which it is possible to advantageously perform effective plasma treatment of large substrates or substrate arrangements.

While in the prior art, in the case of large linear plasmas, e.g. during layer deposition, the layer thicknesses have inhomogeneities that are greater than ±8%, with the inventive ECR plasma source it was possible to produce layer thicknesses of silicon nitride layers over a length of the plasma discharge of approx. 800 mm with inhomogeneities of less than ±2%.

Process control that is very flexible practically is possible by varying the wave power fed in, the shape of the partial plasma chambers, and the position and strength of the magnetic fields of the multi-pole magnetic field arrangement and of a variable gas supply.

The invention is explained in greater detail in the following using four exemplary embodiments.

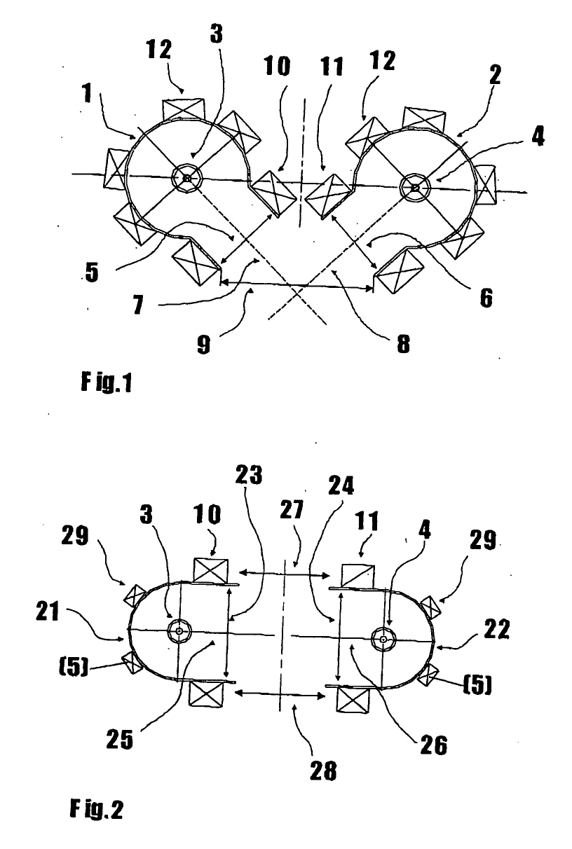

Belonging to exemplary embodiment I, FIG. 1 depicts a section through a schematic of an ECR plasma source having a plasma discharge aperture in which the radial lines between each individual wave distributor and the center of width of each partial plasma discharge aperture are at a 90° angle to one another.

Belonging to exemplary embodiment II, FIG. 2 illustrates a section through a schematic of an ECR plasma source having two plasma discharge apertures in which the radial lines between each individual wave distributor and the center of width of each partial plasma discharge aperture are on one axis and two plasma discharge apertures of the ECR plasma source are arranged at right angles thereto.

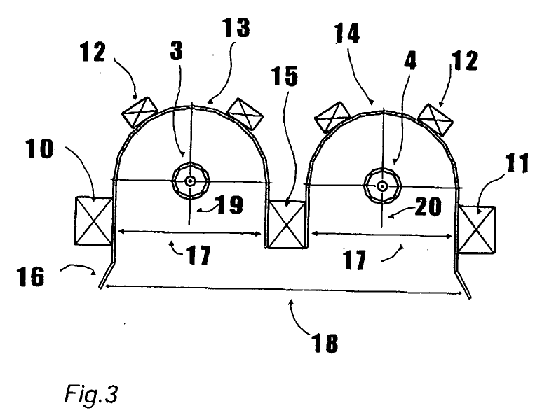

Belonging to exemplary embodiment III, FIG. 3 depicts a section through a schematic of an ECR plasma source having a plasma discharge aperture in which the radial lines between each individual wave distributor and the center of width of each partial plasma discharge aperture are arranged parallel to one another.

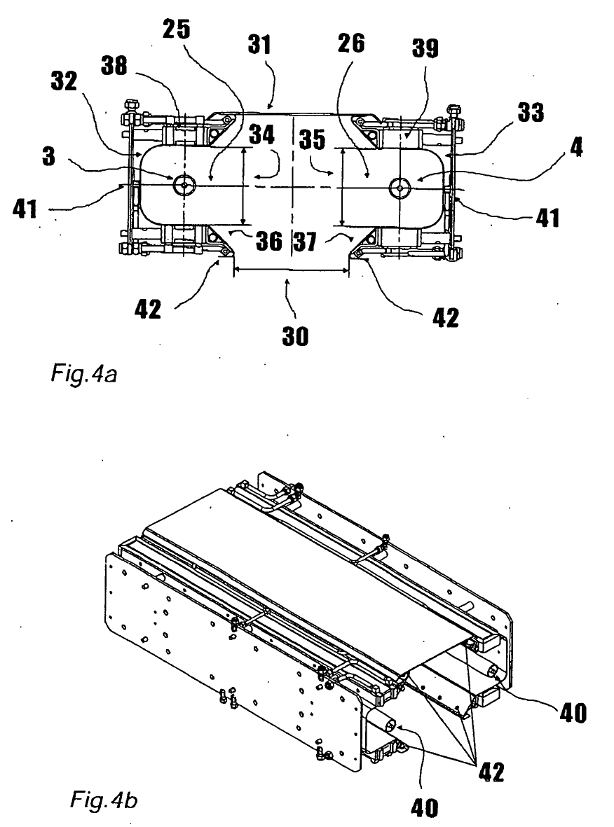

Belonging to exemplary embodiment IV, FIG. 4a depicts a section through a structural design of an ECR plasma source having a plasma discharge aperture in which the radial lines between each individual wave distributor and the center of width of each partial plasma discharge aperture are on one axis and the plasma discharge aperture of the ECR plasma source is arranged at a right angle thereto. FIG. 4b is a perspective view of the ECR plasma source in accordance with FIG. 4a.

### Exemplary Embodiment I

The inventive ECR plasma source in accordance with exemplary embodiment I largely comprises two individual ECR plasma sources. FIG. 1 depicts two partial plasma chambers 1 and 2 that together form the plasma chamber for the ECR plasma source and that are arranged in a vacuum chamber (not shown).

The partial plasma chambers 1 and 2 are embodied tube-shaped and are arranged in each of their interiors coaxial with an individual wave distributor 3, 4. The wave distributors 3, 4 correspond to known solutions and each comprise an internal conductor that can be connected to a device for generating microwaves preferably ranging between 910 MHz and 2.45 GHz. The wave distributors 3 and 4 are enclosed by protective tubes made of quartz glass. The interior space in the protective tubes can be rinsed with a gas and the wave distributors 3 and 4 can be cooled therewith.

The walls of the partial plasma chambers 1 and 2 act as external coaxial waveguides for the microwaves and preferably have in a known manner internal protective linings made of dielectric or conducting materials. One linear partial plasma discharge aperture 5, 6 is present on each tube-shaped partial plasma chamber 1, 2 at its longitudinal axis. The radial lines 7, 8 between each of the individual wave distributors 3, 4 and the center of width of each partial plasma discharge aperture 5, 6 are arranged at a 90° angle to one another. The point of intersection for the radial lines 7, 8 is approximately in the center of the plasma discharge aperture 9 of the ECR plasma source.

One multi-pole magnetic field arrangement 10, 11, with for instance static magnetic fields, is arranged in the area of each partial plasma discharge aperture 5, 6 outside on the partial plasma chambers 1, 2.

Additional multi-pole magnetic field arrangements 12 are arranged outside on the circumference of the partial plasma chambers 1, 2.

All of the multi-pole magnetic field arrangements 10, 11, and 12 are affixed to the partial plasma chambers 1, 2 such that their position and thus the effect of the magnetic field lines can be slightly modified and adapted to specific technological requirements.

The ECR plasma source in accordance with exemplary embodiment I will be described in greater detail in terms of function in the following. The ECR plasma source is situated in a vacuum chamber in which for operating the ECR plasma source a pressure for a carrier gas, e.g. argon, is set to 2×10⁻² mbar. The two wave distributors 3 and 4 are connected to a device for generating microwaves with for instance 915 MHz. The two wave distributors 3 and 4 act as microwave antennas and feed the microwaves into the partial plasma chambers 1 and 2, this causing a plasma to form therein. The magnetic field components act on the plasma in the area of the multi-pole magnetic field arrangements 10 and 11, substantially strengthening the plasma exiting from the plasma discharge aperture 9 of the ECR plasma source. The magnetic field components of the multi-pole magnetic field arrangement 12 also act on the plasma in the same manner.

The multi-pole magnetic field arrangements 10, 11 and 12 are arranged by positioning on the partial plasma chambers 1, 2 such that their magnetic field components, corresponding to the specific technological requirements, effect homogeneous plasma expansion to the plasma discharge aperture 9 of the ECR plasma source with great homogeneity, both in terms of length and width. Thus a substrate (not shown) that is positioned in front of the plasma discharge aperture 9 or is conducted past it can be treated with plasma with great efficiency and maximum quality.

### Exemplary Embodiment II

Belonging to exemplary embodiment II, FIG. 2 is a schematic depiction of an ECR plasma source having two plasma discharge apertures 27 and 28. The positions that are identical to those in exemplary embodiment I are labeled with the same position number in FIG. 2.

Each of two longitudinally extended U-shaped partial plasma chambers 21 and 22, each having one wave distributor 3, 4 that is arranged in the interior concentric with the curvature of the U-shaped partial plasma chambers 21, 22, has partial plasma discharge apertures 23, 24 in the width of the interior diameter. The radial lines 25 and 26 between each of the individual wave distributors 3 and 4 and the center of width of each partial plasma discharge apertures 23 and 24 are on one axis.

The distance between the partial plasma discharge apertures 23, 24 is selected such that formed at right angles and on both sides of the radial lines 25, 26 are two line-type plasma discharge apertures 27 and 28 that act in opposition to one another. Similar to exemplary embodiment I, for influencing the formation of the plasma, multi-pole magnetic field arrangements 10 and 11 are arranged at the plasma discharge apertures 27 and 28 and multi-pole magnetic field arrangements 29 are arranged on the partial plasma chambers 21 and 22.

The function of the ECR plasma source in accordance with exemplary embodiment II is similar to exemplary embodiment I. In application, however, the substrates can be arranged bilaterally in front of the plasma discharge apertures 27 and 28.

### Exemplary Embodiment III

Belonging to exemplary embodiment III, FIG. 3 is a schematic depiction of an ECR plasma source having a plasma discharge aperture 18. The positions that are identical to those in exemplary embodiment I are labeled with the same position number in FIG. 3.

Each of two longitudinally extended U-shaped partial plasma chambers 13 and 14, each having one wave distributor 3, 4 that is arranged in the interior concentric with the curvature of the U-shaped partial plasma chambers 13, 14, has one partial plasma discharge aperture 17 in the width of the interior diameter. The radial lines 19 and 20 between each of the individual wave distributors 3 and 4 and the center of width of each partial plasma discharge aperture 17 are parallel to one another and form the plasma discharge aperture 18 of the ECR plasma source.

Each of the U-shaped partial plasma chambers 13, 14 has, on the exteriorly situated sides of the partial plasma discharge apertures 17, an outwardly angled extension 16, the length and shape of which depends on the given technological conditions.

The distance between the two partial plasma discharge apertures 17 is selected such that the homogeneous individual plasmas at the partial plasma discharge apertures 17 largely combine to create homogeneous plasma at the plasma discharge aperture 18 of the ECR plasma source.

Similar to exemplary embodiment I, multi-pole magnetic field arrangements 10 and 11 are provided on the exterior sides of the partial plasma discharge apertures 17 and additional multi-pole magnetic field arrangements 12 are provided on the partial plasma chambers 13 and 14. In exemplary embodiment III, to be provided between the partial plasma discharge apertures 17 is a multi-pole magnetic field arrangement 15 that acts on both sides of the individual plasmas at the partial plasma discharge apertures 17. With this embodiment, the homogeneity of the plasma can be advantageously influenced at the plasma discharge aperture 18 of the ECR plasma source.

The function of the ECR plasma source in accordance with exemplary embodiment III is similar to that of exemplary embodiment I.

### Exemplary Embodiment IV

Belonging to exemplary embodiment IV, FIG. 4a is a section through a structural design of an ECR plasma source similar to exemplary embodiment II. FIG. 4b is a perspective view of the ECR plasma source.

Exemplary embodiment IV builds on the principle of exemplary embodiment II, i.e. the lines 25 and 26 are on one axis. The essential difference is comprised in that the ECR plasma source has only one plasma discharge aperture 30, while the opposing side is covered with a metal sheet 31.

In the specific embodiment, the distance between the two wave distributors 3 and 4 is 300 mm. The wave distributors 3 and 4, comprising inner tubes with diameters of 8 mm and a protective tube with a diameter of 30 mm, are arranged within U-shaped partial plasma chambers 32 and 33, whereby the U-shape is formed from a rectangular tube with rounded corners that is open on one side. The internal width of this rectangular tube is 110 mm, i.e. the distance between protective tube and inner wall of the partial plasma chambers 32 and 33 is 40 mm. The plasma discharge aperture 30 of the ECR plasma source is 200 mm. Sheet metal guides 36 and 37 are provided between the partial plasma discharge apertures 34 and 35 and the plasma discharge aperture 30.

On both sides of the partial plasma discharge apertures 34 and 35, multi-pole magnetic arrangements 38 and 39 are arranged in pairs immediately at the partial plasma discharge apertures 34 and 35. These are water-cooled, which means that even high ambient temperatures cannot lead to changes in the magnetic field density.

For introducing carrier gases or process gases, linear gas jets 41 are located on the sides of the partial plasma chambers 32 and 33 that face away from the partial plasma discharge apertures 34 and 35 and linear gas jets 42 are located on both sides of the partial plasma discharge apertures 34 and 35.

The magnetic fields of the multi-pole magnetic arrangements 38 and 39 were adjusted such that the ECR plasma is formed preferably in the area of the wave distributors 3 and 4.

In the vicinity of the connecting points 40, for inserting the microwaves (FIG. 4b) the magnetic field is weakened such that the ECR plasma is displaced in the direction of the partial plasma discharge apertures 34 and 35. Because of this the plasma density gradient that results from the increased energy consumption in the vicinity of the connecting points 40 is compensated by a lower magnetic field influence on the plasma generation immediately at the wave distributors 3 and 4. This arrangement results along the partial plasma discharge apertures 34 and 35 in a homogeneous plasma that finally floods the center area of the ECR plasma source with charge carriers. Thus overlaying also leads to a homogeneous plasma area of a certain plasma density at the plasma discharge aperture 30 of the ECR plasma source.

The ECR plasma source is arranged suspended in a vacuum chamber vacuum-tight relative to the environment. The vacuum chamber has a length of 1000 mm and the length of the active plasma zone is approximately 950 mm.

The microwaves that are fed via the wave distributors 3 and 4 into the ECR plasma source have a frequency of 2.45 GHz. Each of the wave distributors 3 and 4 is connected to a microwave generator that can generate a power of 2 kW.

In one further development of the device in accordance with the exemplary embodiment, a grid system (not shown in the drawing) can also be arranged in the area of the plasma discharge aperture 30 outside of the ECR plasma source. Because of this, the ECR plasma source can also be used as an ion beam source. In one such embodiment, preferably multi-pole arrangements with electro-coil arrangements can be used.

In one application of the inventive ECR source, substrates that were to be processed were passed by the plasma discharge aperture 30 continuously. Corresponding to their larger width, large substrate surfaces can also be treated with a homogeneous plasma.

During the deposition of a silicon nitride layer on silicon disks with dimensions of 125 mm×125 mm, 30 such silicon disks in a grid of 5 rows by 5 columns were on a carrier plate at one time. The 6 columns were arranged in the axis direction of the plasma discharge aperture 30 and the carrier plate was caused to pass by continuously in the extension of the 5 rows below the plasma discharge aperture 30.

For producing the silicon nitride layers, ammonia gas was admitted via the gas jets 41 and silane gas was admitted via the gas jets 42. The silicon disks were heated to a defined temperature by means of a radiant heater (not shown in the drawings).

In accordance with the technologically prescribed thickness for the silicon nitride layers to be deposited, approx. 80 nm, the speed of the carrier plate was adjusted such that the required layer thickness was attained in one movement cycle.

The layer thicknesses of the silicon nitride layers at a coating width of approx. 800 mm had inhomogeneities of less than ±2%. In this, it was advantageous that as a result of the relatively homogeneous layer thickness, the refractive index of the silicon nitride layers across the large coating width of 800 mm was in a tolerance range of less than ±1%.

1-8. (canceled)

9. ECR plasma source, comprising
at least two wave distributors,
a high frequency source connected to the wave distributors, for each of the wave distributors a respective subsidiary plasma chamber formed by walls substantially surrounding substantially coaxially a respective one of said wave distributors,
integral with each of the subsidiary plasma chamber walls, a linear plasma discharge aperture for the respective subsidiary plasma chamber,
a magnetic field source comprising a plurality of magnetic poles associated with the linear plasma discharge apertures of the subsidiary plasma chambers, and
the subsidiary plasma chambers being arranged relative to each other to form a main plasma chamber having at least one linear plasma discharge aperture.

10. ECR plasma source according to claim 9, wherein
with respect to each of the subsidiary plasma chambers, a radial line originating at the respective wave distributor and intersecting the center of width of the respective subsidiary plasma discharge aperture, intersects approximately the center of width of one said main plasma discharge aperture.

11. ECR plasma source according to claim 9, wherein
a radial line originating at the wave distributor in one of the subsidiary plasma chambers and passing through the center of width of the plasma discharge aperture for said one plasma chamber is coincident with a radial line originating at the wave distributor in another of the subsidiary plasma chambers and passing through the center of width of said other subsidiary plasma chamber, and a line passing through a center of width of each said main plasma discharge aperture forms an angle with said coincident lines.

12. ECR plasma source according to claim 11, wherein the angle is a right angle.

13. ECR plasma source according to claim 9, wherein
a radial line originating at the wave distributor in one of said subsidiary plasma chambers and intersecting the center of width of the plasma discharge aperture of said one subsidiary plasma chamber is parallel to a radial line originating at the wave distributor in another of said subsidiary plasma chambers and intersecting the center of width of the plasma discharge aperture of said other subsidiary plasma chamber, and the width of one said main plasma discharge aperture is substantially perpendicular to said radial lines.

14. ECR plasma source according to claim 13, wherein said one and said other plasma chambers are side-by-side and a same portion of the magnetic field source is positioned so as to act on both said subsidiary plasma discharge apertures.
